(19) United States
(12) Patent Application Publication
(10) Pub. No.: US 2025/0048912 A1
(43) Pub. Date: Feb. 6, 2025

(54) CARRIER-FREE MULTI-OLEDOS WAFER AND COVER GLASS BONDING METHOD, TOP PLATE-VACUUM ASSEMBLY APPARATUS THEREFOR, BONDING SYSTEM AND METHOD FOR USING THEM

(71) Applicant: Samsung Display Co., LTD., Yongin-si (KR)

(72) Inventor: JONGIK LEE, Yongin-si (KR)

(73) Assignee: Samsung Display Co., LTD., Yongin-si (KR)

(21) Appl. No.: 18/678,171

(22) Filed: May 30, 2024

(30) Foreign Application Priority Data
Aug. 2, 2023 (KR) 10-2023-0100895

(51) Int. Cl. H10K 71/00; H10K 59/12

(52) U.S. Cl. CPC H10K 71/811; H10K 59/1201

(57) ABSTRACT

A cover glass bonding method includes: aligning each wafer of a set of organic light-emitting diode on silicon (OLEDoS) wafers and disposing the set of OLEDoS wafers on an upper table vacuum assembly system (VAS) module of a VAS device without using a carrier glass; disposing an epoxy-drawn cover glass on a lower table VAS module of the VAS device; bonding the set of OLEDoS wafers and the epoxy-drawn cover glass, wherein a working position of each wafer of the set of OLEDoS wafers is individually controlled in the upper table VAS module of the VAS device.

### CROSS-REFERENCE TO RELATED APPLICATION(S)

This application claims priority to and benefits of Korean Patent Application No. 10-2023-0100895 filed on Aug. 2, 2023, in the Korean Intellectual Property Office, the entire contents of which are incorporated herein by reference.

### BACKGROUND

### 1. Technical Field

Embodiments relate to a carrier-free bonding method for organic light-emitting diode on silicon (OLEDoS) wafers and a cover glass, a vacuum assembly system (VAS) device for the OLEDoS wafers and the cover glass, a bonding system using the VAS device, and a control method of the VAS device, and more particularly, to OLEDoS wafers bonded to a cover glass without using a carrier glass. Embodiments relate to a method of bonding carrier-free OLEDoS wafers and a cover glass capable of minimizing and preventing misalignment and poor epoxy drawing, and/or capable of reducing filling amount, a VAS device for the method, a bonding system using the VAS device, and a control method of the VAS device.

### 2. Description of the Related Art

An OLEDoS display is a display made by implementing an organic light-emitting diode (OLED), as a light emitting part, after forming pixels and drivers on a silicon wafer substrate.

During a process of manufacturing the OLEDoS display, a cover glass may be bonded to a circular wafer having a diameter of about 300 mm, after performing an OLED organic film deposition process and a thin film encapsulation process. Thus, a VAS device is required to bond the OLEDoS display and the cover glass.

The method of attaching (or bonding) a cover glass to a circular wafer having a diameter of about 300 mm includes disposing a circular wafer 11 on a square carrier glass 13 (i.e., carrier glass on wafer), as shown in FIG. 1A, and then applying a cover glass 15 (i.e., carrier glass on wafer). In another example, as shown in FIG. 1B, a circular cover glass 15′ and the wafer 11 have the same size (e.g., diameter of about 300 mm), and the circular cover glass 15′ and the wafer 11 are bonded in a one-to-one without using a carrier glass.

Recently, as illustrated in FIG. 1C, for productivity enhancement, a method has been considered of attaching a cover glass 15 on OLEDoS wafers 11A, 11B, 11C, and 11D (e.g., four wafers 11A, 11B, 11C, and 11D) on the square carrier glass 13, which are arranged as a set of wafers 11′ instead of the circular wafer 11 on the square carrier glass 13 of FIG. 1A.

However, the method of bonding the cover glass 15 and the four wafers 11A, 11B, 11C, and 11D disposed on the square carrier glass 13 using the carrier glass 13 may cause mechanical stacking. Thus, the carrier glass 13 may be broken or damaged due to the mechanical stacking.

For example, in case that the press pressure is accumulated in the VAS device, the carrier glass 13 may be highly likely to be cracked beyond the yield point.

Also, in case of arranging four wafers 11A, 11B, 11C, and 11D on the carrier glass 13 as a set of wafers 11′, a necessary tolerance may occur such that the epoxy drawing position may be twisted in case that the cover glass 15 is combined in the VAS device. The twisted epoxy drawing position may lead to a high possibility of causing cell defects due to the inability of high-precision alignment. In the worst case, there is also a problem of high disposal costs as all of the set of wafers 11F should be discarded.

Since the wafers are randomly twisted in case that four wafers are processed rather than a single wafer, there is a problem in that the probability of bonding defects, such as in an epoxy drawing process, increases.

For example, since the carrier glass 13 is heavy, the carrier glass 13 may only be put into the lower table in the VAS device. For example, in case that the epoxy drawing process may be performed on a set of wafers 11′, many epoxy drawing defects or filling defects may occur due to using the set of wafers 11′. Thus, the set of wafers 11′ may be discarded.

### SUMMARY

Embodiments solve these problems, and provide high productivity compared to investment cost without using a carrier glass and without scrapping wafers due to poor epoxy drawing, etc., and facility investment cost compared to production capacity. Embodiments provide a carrier-free bonding method for a plurality of OLEDoS wafers and a cover glass capable of reducing investment costs such as reduction and layout efficiency, a VAS device for the carrier-free bonding method, a bonding system using the VAS device, and a control method of the VAS device.

However, embodiments of the disclosure are not limited to those set forth herein. The above and other embodiments will become more apparent to one of ordinary skill in the art to which the disclosure pertains by referencing the detailed description of the disclosure given below.

In an embodiment, a cover glass bonding method may include: aligning each wafer of a set of organic light-emitting diode on silicon (OLEDoS) wafers and disposing the set of OLEDoS wafers on an upper table vacuum assembly system (VAS) module of a VAS device without using a carrier glass; disposing an epoxy-drawn cover glass on a lower table VAS module of the VAS device; bonding the set of OLEDoS wafers and the epoxy-drawn cover glass, wherein a working position of each wafer of the set of OLEDoS wafers may be individually controlled in the upper table VAS module of the VAS device.

The set of OLEDoS wafers may include first, second, third, and fourth wafers, each of the first, second, third, and fourth wafers has a circular shape having a diameter of about 300 mm, the epoxy-drawn cover glass has a square shape having a size of about 650 mm×750 mm, the first and second wafers have first and second notches arranged side by side on an upper portion of the set of OLEDoS wafers in a first row, and the third and fourth wafers have third and fourth notches arranged side by side on a lower portion of the set of OLEDoS wafers in a second row, and the third and fourth notches are arranged to the first and second notches in a straight line to bond the set of OLEDoS wafers and the epoxy-drawn cover glass.

The epoxy-drawn cover glass may include first, second, third, and fourth vision alignment marks corresponding to the first, second, third, and fourth notches of the first, second, third, and fourth wafers.

In an embodiment, a bonding system of a cover glass may include: a front-end module that takes out wafers from a cassette; an index stage module that forms a set of notch-aligned wafers through notch alignment of first, second, third, and fourth wafers transferred from the front-end module; a first transfer module that takes out the set of notch-aligned wafers formed in the index stage module, inverts the set of notch-aligned wafers one time, and transports and places the set of notch-aligned wafers on an upper table vacuum assembly system (VAS) module of a vacuum assembly system (VAS) device; a second transfer module that transports and arranges a cover glass, which is drawn with epoxy in a cover glass preparation stage, to a lower table VAS module of the VAS device; and the VAS device that bonds the epoxy-drawn cover glass and the set of notch-aligned wafers in a vacuum atmosphere, the set of notch-aligned wafers transferred in a first direction in an inverted state by the first transfer module and disposed on the upper table VAS module, the epoxy-drawn cover glass transferred in a direction opposite to the first direction by the second transfer module and disposed on the lower table VAS module.

Each of the first, second, third, and fourth wafers may have a circular shape having a diameter of about 300 mm, the cover glass may have a square shape having a size of about 650 mm×750 mm, and the set of notch-aligned wafers and the cover glass may be bonded to each other.

The bonding system of the cover glass may further include a vision module that aligns the first, second, third, and fourth wafers using first through fourth notches of the first, second, third, and fourth wafers, respectively; and a control module that controls the front-end module, the index stage module, the first transfer module, the VAS device, and the second transfer module through electrically communicating with the vision module.

The front-end module may include: an extraction robot that takes out the wafers from the cassette, and first and second wafer notch alignment devices that communicate with the control module, the first and second wafer notch alignment device disposed at an end portion of a robot arm of the extraction robot, and the first and second wafer notch alignment devices optimizes a processing time balance of the index stage module.

The index stage module may have a shape and a size corresponding to the shape and the size of the cover glass, and the index stage module may include: an index stage that supports first, second, third, and fourth compartments in which the first, second, third, and fourth wafers are sequentially filled to be notch-aligned, the index stage that informs indexes of the empty first, second, third, and fourth compartments so that the control module operates and controls the extraction robot, the first and second wafer notch alignment devices, and the robot arm, and a stage drive unit that drives the index stage in first, second, third, and fourth type methods in which the first, second, third, and fourth wafers aligned by first and second wafer notch alignment devices are sequentially aligned and arranged by the robot arm, and an index notification unit that informs indexes of the empty first, second, third, and fourth compartments so that the control module operates and controls the extraction robot, the first and second wafer notch alignment devices, and the robot arm, and the first, second, third, and fourth compartments may include: seating pins disposed at a center area of each of the first, second, third, and fourth wafers to seat the first, second, third, and fourth wafers, and index alignment marks corresponding to the first, second, third, and fourth notches of the first, second, third, and fourth wafers.

The first transfer module may include: a robot hand that adsorbs and fixes the set of notch-aligned wafers upward, and a rotatable robot that rotates the robot hand downward to invert the set of notch-aligned wafers, the robot hand may include: a first finger that adsorbs and supports the first and second wafers, and a second finger spaced apart from the first finger by a distance and adsorbing and supporting the third and fourth wafers.

The control module may communicate with the upper table VAS module to confirm that upper table wafer stages of the upper table VAS module is in an empty state before a set of inverted wafers is transferred from the first transfer module, and a robot hand may move the set of inverted wafers forward with respect to the upper table wafer stages, the first, second, third, and fourth wafers of the set of notch-aligned wafers may be aligned with respect to each of the upper table wafer stages, and a vacuum chuck may be lowered to adsorb each wafer of the set of notch-aligned wafers, the robot hand may move upward and backward from the set of notch-aligned wafers, and in case that the robot hand moves upward and backward from the set of notch-aligned wafers, the vacuum chuck may be raised to control the first, second, third, and fourth wafers of the set of wafers to be disposed on the upper table wafer stages, and the vacuum chuck may move up and down between first and second fingers of the robot hand.

In an embodiment, a vacuum assembly system (VAS) device for a bonding system for a plurality of organic light-emitting diode on silicon (OLEDoS) wafers and a cover glass may include: an upper table VAS module disposed on an upper side of the VAS device; and a lower table VAS module disposed on a lower side of the VAS device, wherein the upper table VAS module may include: first, second, third, and fourth upper table wafer stages on which first, second, third, and fourth wafers of a set of four wafers are respectively seated in notch alignment; a UVW alignment stage including first, second, third, and fourth UVW alignment stages that are connected to the first, second, third, and fourth upper table wafer stages and independently perform 3-axis UVW alignment on each of the first, second, third, and fourth upper table wafer stages; a vacuum chuck unit including first, second, third, and fourth vacuum chucks that place the first, second, third, and fourth wafers on the first, second, third, and fourth upper table wafer stages, respectively; a vacuum chuck driving unit including first, second, third, and fourth vacuum chuck driving units that elevate and lower the vacuum chuck unit; and first, second, third, fourth, fifth, sixth, seventh, and eighth high-resolution vision units provided in pairs for each of the first, second, third, and fourth upper table wafer stages and communicating with a control module so that the UVW alignment stage is adjusted in a 3-axis UVW direction.

The first, second, third, and fourth upper table wafer stages may be disposed in an upper chamber, the UVW alignment stage may be disposed outside the upper chamber, the vacuum chuck driving unit may be disposed outside the UVW alignment stage, the first, second, third, fourth, fifth, sixth, seventh, and eighth high-resolution vision units may correspond to the first, second, third, and fourth upper table wafer stages, respectively, and may be disposed below the first, second, third, and fourth upper table wafer stages.

The UVW alignment stage may include: first, second, third, and fourth base substrates connected through a communication hole of the upper chamber, and first, second, third, and fourth UVW drivers corresponding to the first, second, third, and fourth upper table wafer stages, the first, second, third, and fourth UVW drivers that drive the first, second, third, and fourth base substrates in three axes to compensate for displacement of working positions of the first, second, third, and fourth base substrates.

The vacuum chuck unit of the upper table VAS module may include: a vacuum chuck pad connected to each of the upper table wafer stages, a vacuum chuck pipe that provides vacuum negative pressure to the vacuum chuck pad, and a vacuum chuck pipe ring housing that prevents leak between a bottom of the vacuum chuck pipe and the vacuum chuck pad, and the vacuum chuck pipe may be at least partially connected to the vacuum chuck driving unit to raise and lower the vacuum chuck pad to be exposed outside of the upper chamber.

The VAS device for the bonding system may further include: bellows disposed in the upper chamber to provide negative vacuum pressure to the first, second, third, and fourth upper table wafer stages to independently drive the first, second, third, and fourth upper table wafer stages and the UVW alignment stage; and adapters connecting a lower part of the UVW alignment stage and an upper part of the upper chamber, and wherein the bellows and the adapters may overlap the first, second, third, and fourth upper table wafer stages and the UVW alignment stage, respectively.

The VAS device for the bonding system may further include: a second transfer module including: a first transfer hand that transfers the cover glass to the lower table VAS module, and a second transfer hand that transfers the set of four wafers and the cover glass that are bonded to each other, wherein the first transfer hand and the second transfer hand may be disposed opposite to each other, and are connected to a transfer passage.

In an embodiment, a control method of a bonding system of a plurality of carrier-free organic light-emitting diode on silicon (OLEDoS) wafers and a cover glass may include: controlling an extraction robot to take out wafers from a cassette loaded in a front-end module of the bonding system by a control module; controlling an index stage module to align the wafers taken out by the extraction robot using notches of the wafers; sequentially arranging first, second, third, and fourth wafers among the wafers to form a set of notch-aligned wafers in case that it is determined that first, second, third, and fourth compartments of an index stage are empty through communication with index stage of the index stage module; communicating with a first transfer module to take out the set of notch-aligned wafers, to invert the set of notch-aligned wafers one time, and controlling transfer and placement of the set of notch-aligned wafers to an upper table vacuum assembly system (VAS) module of a VAS device; and communicating with a second transfer module and controlling transfer and arrangement of the cover glass drawn with epoxy in a cover glass preparation stage to a lower table VAS module of the VAS device; and controlling the upper table VAS module and the lower table VAS module of the VAS device to bond the set of notch-aligned wafers disposed in the upper table VAS module by the first transfer module in an inverted state in a first direction, and the epoxy-drawn cover glass disposed in the lower table VAS module by the second transfer module in a second direction opposite to the first direction, under a vacuum atmosphere.

The control method of the bonding system may further include: communicating with a vision module for alignment of the first, second, third, and fourth wafers using the first, second, third, and fourth notches of the first, second, third, and fourth wafers, respectively; controlling working positions of the front-end module, the index stage module, the first transfer module, the VAS device, and the second transfer module through communicating with the vision module.

The control method of the bonding system may further include: communicating with the upper table VAS module and confirming that an upper table wafer stage of the upper table VAS module is empty before the set of inverted notch-aligned wafers is transferred from the first transfer module; moving the set of inverted notch-aligned wafers forward with respect to the upper table wafer stage by a robot hand; aligning the first, second, third, and fourth wafers of the set of notch-aligned wafers with respect to each of the upper table wafer stages; adsorbing each wafer of the set of notch-aligned wafers by lowering a vacuum chuck in the upper table VAS module; and placing the first, second, third, and fourth wafers of the set of notch-aligned wafers on the upper table wafer stage by moving the robot hand upward and backward from the set of notch-aligned wafers such that the vacuum chuck of the upper table wafer stage may move up.

The control method of the bonding system may further include: disposing the wafers, which are notch-aligned by first and second wafer notch alignment devices, one by one to the first, second, third, and fourth compartments of the index stage of the index stage module; disposing the wafers, which are loaded into the index stage, on a seating pin disposed in a center area of each of the first, second, third, and fourth compartments and driven independently; driving the index stage according to first, second, third, and fourth angular driving types in which the notches of the first, second, third, and fourth wafers are aligned in case that the first, second, third, and fourth compartments are sequentially filled with the first, second, third, and fourth wafers; and forming a set of wafers, which are filled in the first, second, third, and fourth compartments in order with the first, second, third, and fourth wafers being notched-aligned in first, second, third, and fourth angular driving types.

### BRIEF DESCRIPTION OF THE DRAWINGS

FIG. 1A is a schematic diagram explaining a bonding method of a wafer and a cover glass in a one-to-one using a carrier glass in manufacturing a conventional OLEDoS display.

FIG. 1B is a schematic diagram explaining a bonding method of a wafer and a cover glass in a one-to-one without using a carrier glass in manufacturing a conventional OLEDoS display.

FIG. 1C is a schematic diagram of a method of bonding wafers and a cover glass using a carrier glass in case of manufacturing an OLEDoS display.

FIG. 2 is a schematic diagram illustrating a method of bonding a set of carrier-free OLEDoS wafers and a cover glass according to an embodiment.

FIG. 3 is an overall schematic diagram of a bonding system for carrier-free OLEDoS wafers and a cover glass according to an embodiment.

FIG. 4 is a schematic diagram explaining the configuration and operation of the front-end module and the index stage of FIG. 3.

FIG. 5 is a schematic diagram explaining the configuration and operation of a first transfer module of FIG. 3.

FIG. 6 is a schematic diagram explaining in detail the loading operation of the first transfer module of FIG. 3.

FIGS. 7A, 7B, 7C, 7D, 7E, and 7F are a schematic perspective view, a schematic perspective view from below, a schematic front view, a schematic front longitudinal sectional view of FIG. 7C, a schematic rear longitudinal sectional view of FIG. 7C, and a schematic view for explaining the operation of the vacuum chuck for an upper table VAS module of FIG. 3, respectively.

FIG. 8 is a flowchart illustrating a bonding method between a set of carrier-free OLEDoS wafers and a cover glass according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z—axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

Hereinafter, a method for attaching carrier-free OLEDoS wafers and a cover glass according to an embodiment, a vacuum assembly system (VAS) device for the method, a bonding system and a bonding method using the VAS device will be described in detail with reference to the accompanying drawings.

Hereinafter, the same reference numerals are used for technical elements that perform the same functions, and repeated detailed descriptions are omitted to avoid redundant description.

For example, the embodiments described below are shown by way of example to effectively show preferred embodiments, and should not be construed to limit the scope of the invention.

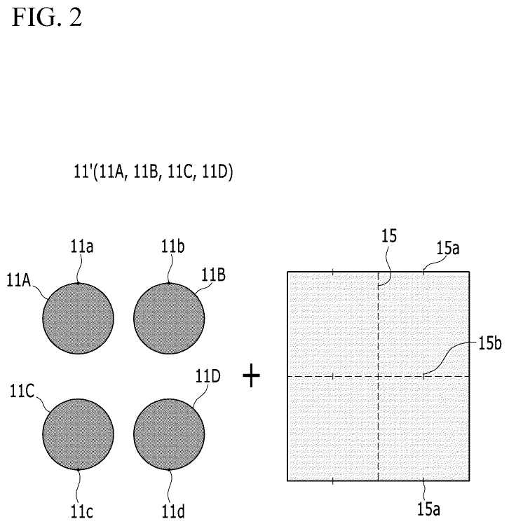

FIG. 2 is a schematic diagram illustrating a method of bonding a set of carrier-free organic light-emitting diode on silicon (OLEDoS) wafers and a cover glass according to an embodiment.

A method of bonding a set of carrier-free OLEDoS wafers and a cover glass according to an embodiment may include four circular wafers 11A, 11B, 11C, and 11D having about 300 mm diameter without using a carrier glass. In a state where the set of wafers 11′ is disposed at a higher position, a square cover glass 15 having a typical size of about 650 mm×750 mm may be disposed at a lower position to perform the bonding process.

For example, a set of four circular wafers 11′ (11A, 11B, 11C, and 11D) having about 300 mm diameter may be simultaneously inverted and transferred to a vacuum assembly system (VAS) device (e.g., upper table VAS module), and a square cover having a conventional size of 650 mm×750 mm may be transferred to the VAS device (e.g., lower table VAS module). In case that the four circular wafers 11A, 11B, 11C, and 11D having about 300 mm diameter are bonded to the cover glass 15, since the four circular wafers 11A, 11B, 11C, and 11D having about 300 mm diameter are each aligned by using at least two or more vision alignment marks, alignment may be performed to have high precision.

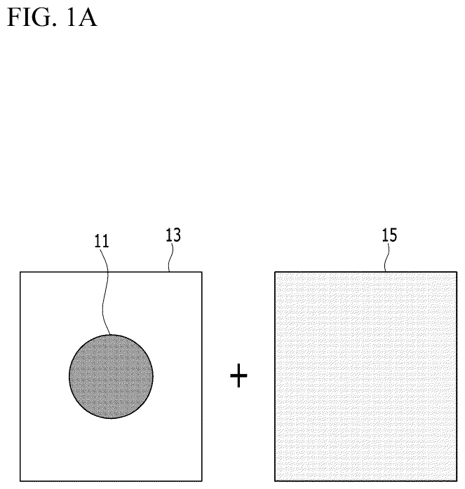

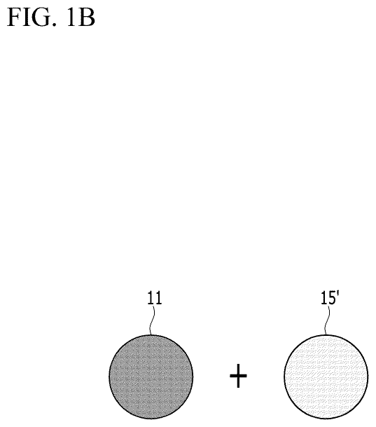

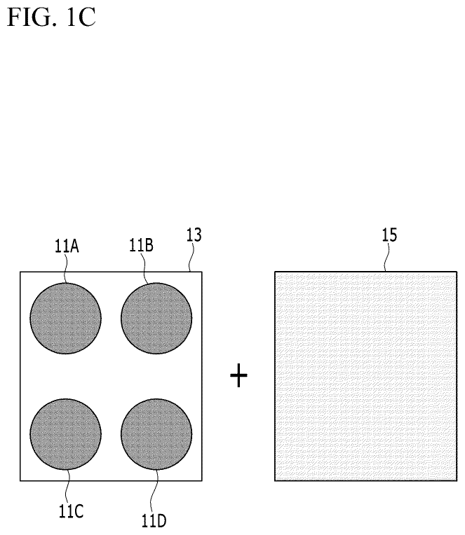

The square cover glass 15 may be the same as (or similar to) the square cover glass 15 of the typical production line shown in FIG. 1A. The square cover glass 15 may further have four vision alignment marks 15a corresponding to notches 11a, 11b, 11c, and 11d of the four wafers and two vision alignment dummy marks 15b in the center area thereof.

According to a method of bonding a carrier-free set of OLEDoS wafers 11′ and a cover glass 15 according to an embodiment, four circular wafers 11′ of a set of OLEDoS wafers 11′ may be formed without using a carrier glass. In case that circular wafers 11A, 11B, 11C, and 11D may be aligned respectively, and disposed on the upper table VAS module of the vacuum assembly system (VAS) device, the circular wafers 11A, 11B, 11C, and 11D may be bonded to the cover glass 15 disposed on the lower table VAS module of the VAS device, and an epoxy drawing process and a filling process may be performed on the cover glass 15 disposed on the lower table VAS module. Thus, the epoxy drawing process and the filling process may be performed before bonding the circular wafers 11A, 11B, 11C, and 11D and the cover glass 15. As a result, a typical equipment may be used without the need for separate equipment development.

Therefore, in preparation for a conventional bonding method for OLEDoS wafers and a cover glass in a one-to-one of FIGS. 1A and 1B, although the processing time for the standard process of the typical VAS device is the same, the four OLEDoS wafers 11′ and the cover glass 15 may be bonded at once. Thus, since the four OLEDoS wafers 11′ are simultaneously bonded to the cover glass 15, it is possible to ensure four times the productivity by reducing the processing time.

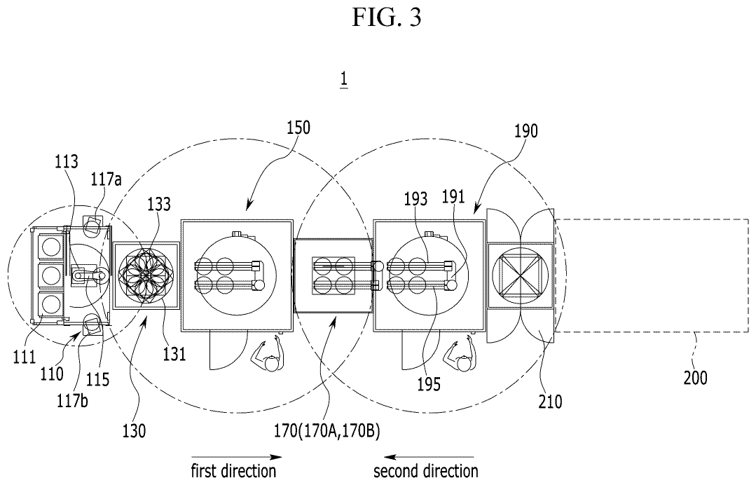

Referring to FIGS. 3, 4, 5, and 6, carrier-free sheets according to an embodiment for implementing a method of bonding a set of carrier-free OLEDoS wafers 11′ and a cover glass 15 according to an embodiment with reference to FIGS. 3, 4, 5, and 6, a detailed explanation of the bonding system 1 for a set of OLEDoS wafer 11′ and a cover glass 15 will be given.

FIG. 3 is an overall schematic diagram of a bonding system 1 for carrier-free OLEDoS wafers 11′ and a cover glass 15 according to an embodiment.

As shown in FIG. 3, the bonding system 1 for carrier-free OLEDoS wafers 11′ and a cover glass 15 according to an embodiment may have a front-end module 110 inputting wafers 11′ from a cassette 111 in units of sheets (or one by one), an index stage module 130 in which a set of four wafers 11′ input from the front-end module 110 may be each notch-aligned, and a first transfer module 150 taking out the set of four wafers 11′ from the index stage module 130 as a unit, flipping the set of four wafers 11′, and placing the set of four wafers 11′ on the upper table VAS module 170A of the VAS device 170. After an epoxy drawing process performed on the cover glass 15 in the first transfer module 150 and the cover glass preparation stage 200, the epoxy-drawn cover glass 15′ supplied through the passage 210 may be transferred to the VAS device 170. The bonding system 1 may further include a second transfer module 190 which inputs the epoxy-drawn cover glass 15′ to the lower table VAS module 170B.

The first transfer module 150 may input the set of wafers 11′ to the VAS device 170 in a first direction, and the second transfer module 190 may supply the epoxy-drawn cover glass 15′ to the VAS device 170 in a second direction opposite to the first direction. The set of wafers 11′ and the epoxy-drawn cover glass 15′ may be bonded to each other in the VAS device 170, and the second transfer module 190 may discharge the set of wafers and the epoxy-drawn cover glass 15′, which are bonded, in the first direction after bonding the set of wafers 11′ and the epoxy-drawn cover glass 15′.

The VAS device 170 may include a set of four wafers 11′, which is disposed on the upper table VAS module 170A and transferred by the first transfer module 150 in the first direction, and the square cover glass (or epoxy-drawn cover glass) 15′, which is transferred by the second transfer module 190 in the second direction. The square cover glass 15′ disposed on the lower table VAS module 170B may be bonded to the set of four wafers 11′ disposed on the upper table VAS module 170A in the VAS device 170 in a vacuum atmosphere.

According to an embodiment, a bonding system 1 for a set of carrier-free OLEDoS wafers 11′ and a cover glass 15 may include a front-end module 110, an index stage module 130, a first transfer module 150, a vacuum assembly system (VAS) device 170, and a second transfer module 190. The bonding system 1 may further include a vision module 180 used to micro-align the first to fourth wafers 11A, 11B, 11C, and 11D of the set of wafers 11′ by using the first to fourth notches 11a, 11b, 11c, and 11d of the first to fourth wafers 11A, 11B, 11C, and 11D, respectively, and a control module 300 that communicates electrically with the vision module 180 and controls the front-end module 110, the index stage module 130, the first transfer module 150, the VAS device 170, and the second transfer module 190, so as to align each of the first to fourth wafers 11A, 11B, 11C, and 11D of the set of wafers 11′. Thus, the bonding process may be performed in an aligned state.

TABLE 1
Comparative table of advantages and disadvantages of an
embodiment and comparative examples

| | | | epoxy | | | | | |
|---|---|---|---|---|---|---|---|---|
| | | | drawing | carrier | | | wafer | Investment |
| Item | Input type | | process | glass | alignment | Productivity | Loss | cost |
| Comparative | wafer | lower | wafer | existence | low | 1 | high | low |
| Example 1 | | plate | | | | | | |
| (bonding in | | | | | | | | |
| one-to-one | | | | | | | | |
| using carrier | | | | | | | | |
| glass) | | | | | | | | |
| Comparative | wafer | upper | cover | non- | high | 1 | low | high |
| Example 2 | | plate | glass | existence | | | | |
| (bonding in | | | | | | | | |
| one-to-one | | | | | | | | |
| without | | | | | | | | |
| carrier glass) | | | | | | | | |
| embodiment | wafer | upper | cover | non- | high | 4 | low | same |
| | | plate | glass | existence | | | | |

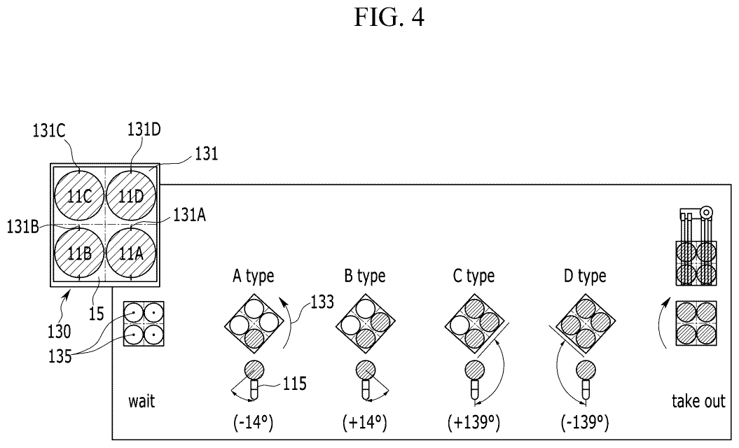

As shown in Table 1, in the bonding system 1 for carrier-free OLEDoS wafers 11′ and a cover glass 15 according to an embodiment, since the carrier glass is not used, the carrier glass itself may not be broken or damaged by the VAS device 170, bonding failure between the wafer 11′ on the carrier glass and the cover glass 15 may be prevented, and productivity may be improved compared to the case where the single circular wafer 11 and the square cover glass 15 are bonded in a one-to-one. Since the epoxy drawing process is not performed on the wafer 11 but on the cover glass 15, various problems such as poor epoxy drawing may be reduced or prevented, it may be suitable for mass production, and maintenance costs may be reduced. Referring to FIG. 4 together with FIG. 3, how the wafers 11A, 11B, 11C, and 11D, which are input as a unit of the front-end module 110, are notch-aligned in the index stage module 130 to form a set of four wafers 11′ will be described in detail.

FIG. 4 is a schematic diagram illustrating the configuration and operation of the front-end module 110 and the index stage module 130 of FIG. 3.

As again shown in FIG. 3, in the bonding system 1 for the set of OLEDoS wafers 11′ and the cover glass 15 according to an embodiment, the front-end module 110 may use the typical front-end module. In order to optimize the balance of the workable production time, e.g., the processing time, of the index stage module 130, a robot arm 115 may be controlled to interlock with the first and second wafer notch alignment devices 117a and 117b on sides (e.g., opposite sides) of an extraction robot 113 that extracts the wafer from the cassette 111 based on the input direction of the index stage module 130 of the extraction robot 113.

The set of wafers 11′ may include four wafers including first, second, third, and fourth wafers 11A, 11B, 11C, and 11D, each of the four wafers may have a circular shape having a diameter of about 300 mm, the cover glass 15 may have a square shape having a size of about 650 mm×750 mm. The first and second wafers 11A and 11B having first and second notches 11a and 11b may be arranged side by side on the top (or upper portions) of the set of wafers 11′ in a first row. The third and fourth wafers 11C and 11D having third and fourth notches 11c and 11d may be arranged side by side at the bottom (or lower portions) of the set of wafers 11′ may be disposed side by side in a second row.

The third and fourth notches 11c and 11d may be disposed on a straight line with respect to the first and second notches 11a and 11b, so that four wafers of the set of wafers 11′ may be precisely aligned to each other.

The index stage module 130 may be made in a size and a shape corresponding to the shape and size of the cover glass 15, and may have an index stage 131 having four compartments (or first, second, third, and fourth compartments) in which four wafers 11A, 11B, 11C, and 11D are each inserted (or arranged) in a counterclockwise direction. The index stage module 130 may include a stage driving part 133 that rotates the index stage 131 so that the vision alignment marks 15a and/or 15b of the first, second, third, and fourth compartments 131A, 131B, 131C, and 131D of the index stage 131 may be aligned to the notches 11a, 11b, 11c, and 11d of the first, second, third, and fourth wafers 11A, 11B, 11C, and 11D.

In case that the robot arm 115 of the front-end module 110 rectilinearly reciprocates in the wafer input direction, the notches 11a, 11b, 11c, and 11d of the four wafers 11A, 11B, 11C, and 11D, which are disposed on the robot arm 115, may be aligned to the vision alignment marks 15a and/or 15b of the first, second, third, and fourth compartments 131A, 131B, 131C, and 131D of the index stage 131 by rotating by certain angles (e.g., about −14 degrees, about 14 degrees, about 139 degrees, and about −139 degrees). Considering the wafer input direction of the robot arm 115 and the size of the index stage 131 and the size of each of the OLEDoS wafers 11′, the index stage 131 may swing or rotate the first, second, third, and fourth compartments 131A, 131B, 131C, and 131D to be arranged side by side by about −14 degrees, about 14 degrees, about 139 degrees, and about −139 degrees with respect to the standby state. The index stage 131 may include a stage driving part 133 for swing driving the index stage 131 so that the compartments 131A, 131B, 131C, and 131D may be disposed.

The index stage 131 may transmit information on empty compartments among the first, second, third, and fourth compartments 131A, 131B, 131C, and 131D (or indexes of the empty first, second, third, and fourth compartments) to the front-end module 110, and the front-end module 110 may align and may insert the wafer according to the angles of the first, second, third, and fourth compartments 131A, 131B, 131C, and 131D.

The robot arm 115 of the front-end module 110 may sequentially transfer the wafers 11′ including notches 11a, 11b, 11c, and 11d, which are aligned to the index stage module 130 one by one by the first and second wafer notch alignment devices 117a and 117b. In the index stage 131, the wafers 11′ may be aligned and input to the first, second, third, and fourth compartments 131A, 131B, 131C, and 131D, which are empty.

The wafer loaded into the index stage 131 may be seated on the seating pin 135 installed in the center area of each of the first, second, third, and fourth compartments 131A, 131B, 131C, and 131D. The index stage 131 may be adsorbed and fixed by an independently controlled adsorption device so that the index stage 131 may not move in case that the stage driving part 133 swings.

In case that the first, second, third, and fourth compartments 131A, 131B, 131C, and 131D are all filled with a set of four wafers 11′ aligned by using the notches 11a, 11b, 11c, and 11d and the alignment marks by the stage driving part 133 of the index stage 131, the index stage 131 may be in a carrying-out state in which the wafers of the set of four wafers 11′ are arranged side by side in the input direction of the wafer in the same manner as the standby state.

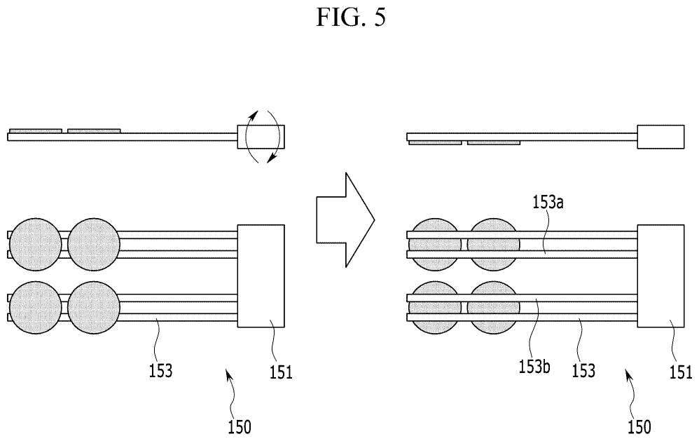

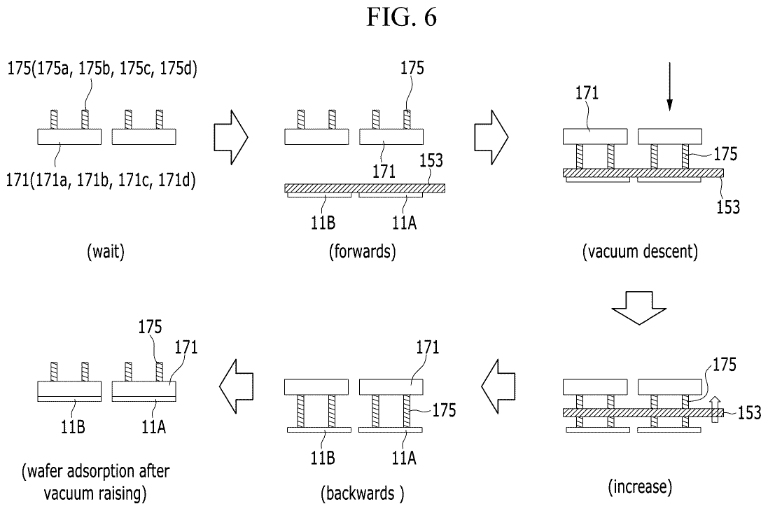

Referring to FIGS. 5 and 6, the first transfer module 150 may take out and flip (or invert) a set of four wafers 11′ transferred from the index stage module 130 as a unit, and may input the inverted set of four wafers 11′ into the VAS device 170. The configuration and operation of inputting the set of four wafers 11′ into the upper table VAS module 170A of the VAS device 170 will be described in detail.

FIG. 5 is a schematic diagram illustrating the configuration and operation of the first transfer module 150 of FIG. 3, and FIG. 6 is a schematic diagram illustrating in detail the loading operation of the first transfer module 150 of FIG. 3.

As shown in FIG. 5, in the bonding system 1 for carrier-free OLEDoS wafers 11′ and a cover glass 15 according to an embodiment, the first transfer module 150 may include a rotatable rotary robot 151 and a robot hand 153 attached to the rotatable robot 151. The rotatable robot 151 may be rotatable and may adsorb the set of wafers 11′ upward and flip (or invert) the set of wafers 11′ downward.

The first transfer module 150 may adsorb the set of wafers 11′ aligned in the index stage module 130 onto the robot hand 153 and may move the robot hand 153 attached to the rotatable robot 151. The first transfer module 150 may be flipped (or inverted) downward to maintain the set of wafers 11′ in an inverted state.

As shown in FIG. 6, the upper table VAS module 170A of the VAS device 170 may include four upper table wafer stages 171a, 171b, 171c, and 171d, and vacuum chucks 175a, 175b 175c, and 175d that each communicate with the upper table wafer stages 171a, 171b, 171c, and 171d.

In the VAS device 170, the upper table wafer stages 171a, 171b, 171c, and 171d may remain empty before the inverted set of wafers 11′ is loaded from the first transfer module 150.

The robot hand 153 reversed (or inverted) downward in the first transfer module 150 may move forward to align the wafers 11A, 11B, 11C, and 11D to the upper table wafer stages 171a, 171b, 171c, and 171d of the VAS device 170. In case that each of the wafers 11A, 11B, 11C, and 11D of the set of wafers 11′ is aligned on the upper table wafer stages 171a, 171b, 171c, and 171d, the vacuum chucks 175a, 175b, 175c, and 175d, respectively, by descending, may adsorb each of the wafers 11A, 11B, 11C, and 11D of the set of wafers 11′.

In a state in which the vacuum chucks 175a, 175b, 175c, and 175d descend and adsorb each wafer of the set of wafers 11′, respectively, the robot hand 153 may move upward and backward.

The robot hand 153 may have a pair of first and second fingers 153a and 153b arranged at a certain distance from the center area of two wafers arranged to be parallel to the input direction of the wafer as shown in FIG. 5, and the vacuum chucks 175a, 175b 175c, and 175d attached to each of the upper table wafer stages 171a, 171b, 171c, and 171d may freely move up and down between the certain distance between the first and second fingers 153a and 153b.

In case that the robot hand 153 moves upward and backward with respect to a set of wafers 11′, the vacuum chucks 175a, 175b, 175c, and 175d attached to the upper table wafer stages 171a, 171b, 171c, and 171d, respectively, may move up. Thus, the set of wafers 11′ may be disposed on the upper table wafer stages 171a, 171b, 171c, and 171d.

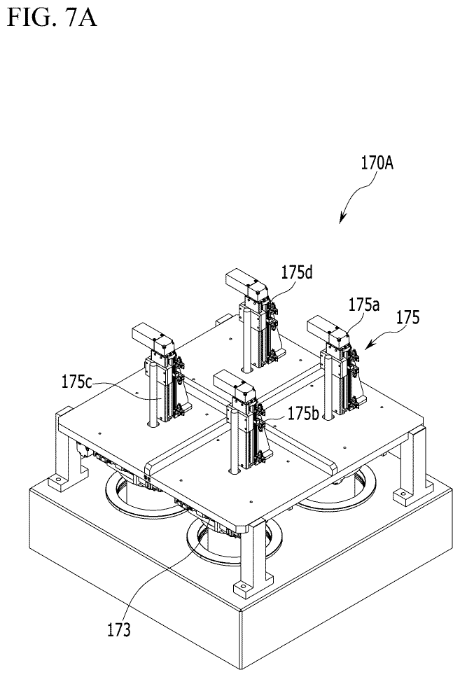

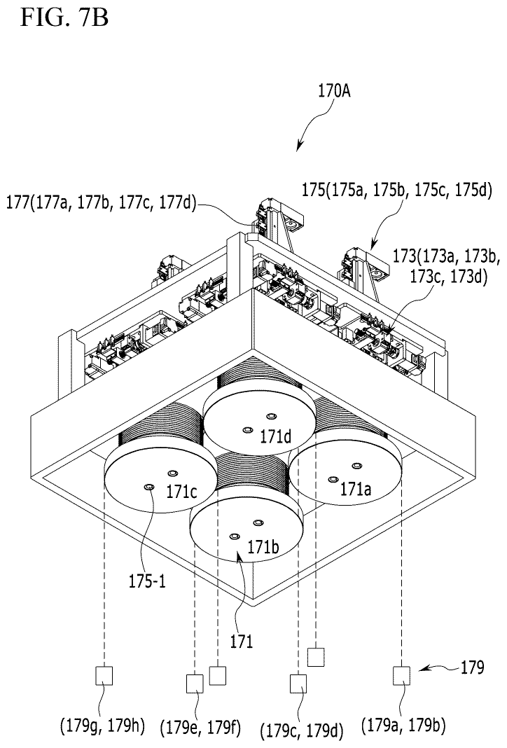

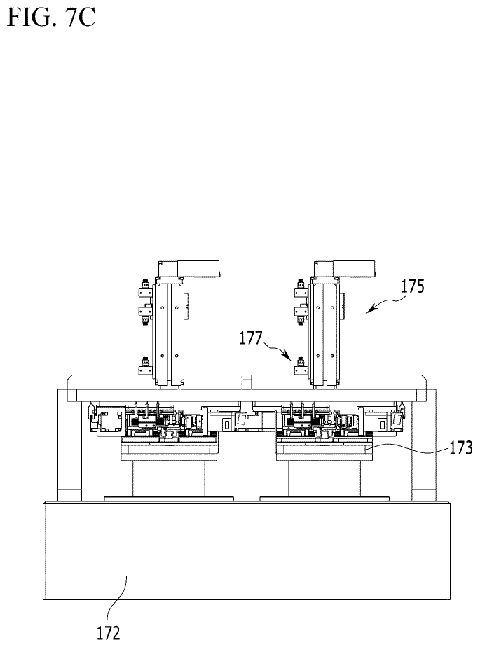

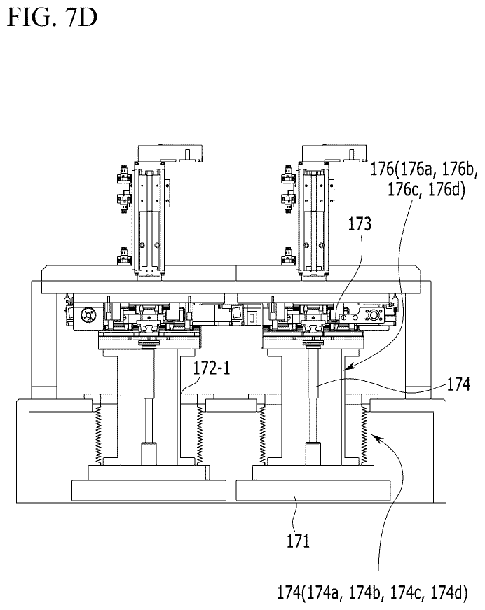

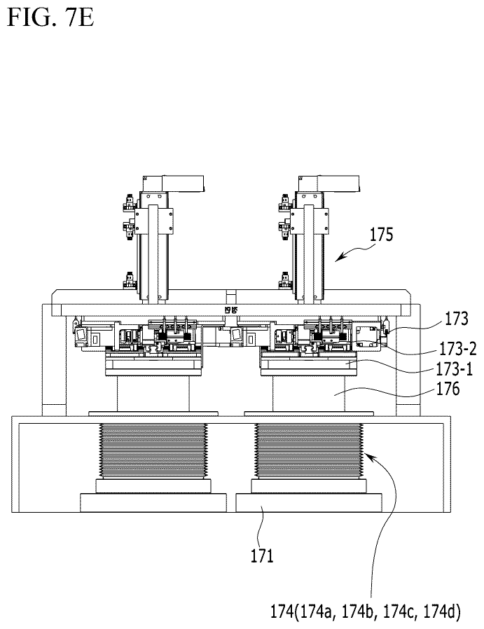

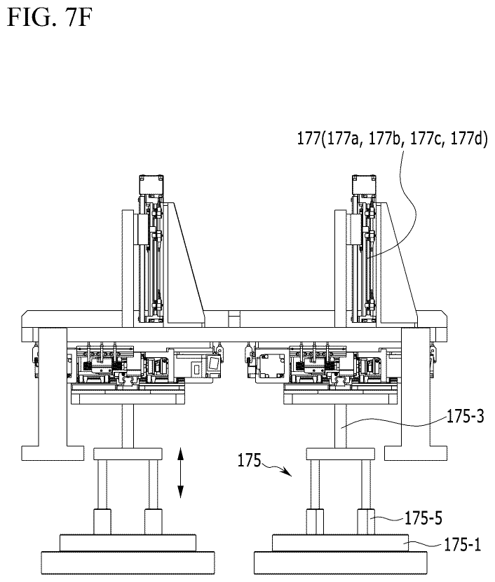

Referring to FIGS. 7A, 7B, 7C, 7D, 7E, and 7F, in the OLEDoS wafer 11′ and cover glass 15 disposed in the bonding system 1 according to an embodiment, configuration of a VAS device for bonding four aligned OLEDoS wafers 11′ as a set to a cover glass 15, and the operation method is explained in detail.

FIGS. 7A to 7F, respectively, are schematic diagrams illustrating the VAS device in FIG. 3, and are a schematic top view, a schematic bottom view, a schematic front view, a schematic forward longitudinal section view in FIG. 7C, a schematic rear longitudinal section view in FIG. 7C, and a schematic view for explaining the operation of the vacuum chuck.

As shown in FIGS. 7A and 7B, the upper table VAS module 170A of the VAS device 170 of the bonding system 1 for carrier-free OLEDoS wafers 11′ and a cover glass 15 according to an embodiment may include the upper table wafer stage 171, a UVW alignment stage 173, a vacuum chuck driving unit 177, and a vision unit 179. The upper table wafer stage 171 may include first to fourth upper table wafer stages 171a, 171b, 171c, and 171d on which the four wafers 11A, 11B, 11C, and 11D of the set of wafers 11′ are disposed, respectively. The UVW alignment stage 173 may include first to fourth UVW alignment stages 173a, 173b, 173c, and 173d that are connected to the first to fourth upper table wafer stages 171a, 171b, 171c, and 171d and independently align the first to fourth upper table wafer stages 171a, 171b, 171c, and 171d in the three-axis UVW direction, respectively. The vacuum chuck driving unit 177 may include first to fourth vacuum chuck driving units 177a, 177b, 177c, and 177d that move up and down the vacuum chucks 175a, 175b, 175c, and 175d. The vision unit 179 may include first to eighth high-resolution vision units 179a to 179h for fine-tuning the UVW alignment stage 173 in the 3-axis UVW direction, and each of the first to eighth high-resolution vision units 179a to 179h may be installed in pairs on the first to fourth wafer stages 171a, 171b, 171c, and 171d.

The upper table wafer stage 171 may have a circular shape having a size of about 305 mm corresponding to the size of the four wafers 11A, 11B, 11C, and 11D of the set of wafers 11′ having about 300 mm diameter, and the upper table wafer stage 171 may have four square shapes. At least two or more vacuum chuck pads 175-1 disposed in an upper chamber 172 (in FIG. 7C) and spaced apart from each other in the upper table wafer stage 171 may be disposed to seat each of the set of wafers 11′.

The UVW alignment stage 173 may include a base substrate 173-1 and a UVW driver 173-2 which corrects the displacement of a base substrate 173-1 (in FIG. 7E) and the working position of the base substrate 173-1, respectively, in the X-axis, Y-axis, and 6-axis. Thus, the UVW alignment stage 173 may have high precision and high response.

The base substrate 173-1 may be connected to the upper chamber 172 and may be supported in case that the base substrate 173-1 is pressed by the lower table VAS module 170B, which will be briefly described later.

The UVW driving unit 173-2 may use X-axis and Y-axis linear servo motors, and may use a 6-axis direct drive motor.

As shown in FIG. 7D, the upper table vacuum chuck unit 175 (in FIG. 7F) may include a vacuum chuck pads 175-1, a vacuum chuck pipe 175-3, and a vacuum chuck pipe ring housing 175-5. The vacuum chuck pads 175-1 may be symmetrically spaced apart from each other, may communicate with each other, and may be disposed on the upper table wafer stages 171. The vacuum chuck pipe 175-3 may be connected to a vacuum pump and controlled to apply vacuum negative pressure to the vacuum chuck pads 175-1. The vacuum chuck pipe ring housing 175-5 may provide airtight connection between the vacuum chuck pipe 175-3 and the vacuum chuck pad 175-1.

The vacuum chuck pipe ring housing 175-5 may be installed to prevent or block air leakage from the vacuum pipe 175-3 in case that the vacuum chuck pads 175-1 move up and down.

The upper table vacuum chuck unit 175 may be disposed on top (or upper portion) of the upper chamber 172. The upper table vacuum chuck unit 175 may raise and lower the upper table wafer stage 171 to be exposed outside the upper chamber 172 by the vacuum chuck driving unit 177.

Each of the upper table vacuum chuck units 175 may be driven such that each wafer of the set of wafers 11′ may be transferred and adsorbed by each of the upper table wafer stages 171.

The upper chamber 172 may further include bellows 174 including four independent first to fourth bellows 174a, 174b, 174c, and 174d and an adapter 176 including first to fourth adapters 176a, 176b, 176c, and 176d. The bellows 174 and the adapter 176 may be installed between the first to fourth upper table wafer stages 171a, 171b, 171c, and 171d, which are accommodated in the above upper chamber 172, and the first to fourth UVW alignment stages 173a, 173b, 173c, and 173d which are disposed outside the upper chamber 172 in the atmosphere such that first to fourth UVW alignment stages 173a, 173b, 173c, and 173d may be smoothly and independently operated.

The first to fourth adapters 176a, 176b, 176c, and 176d may be each connected to lower portions of the first to fourth UVW alignment stages 173a, 173b, 173c, and 173d, and may be each connected to the first to fourth bellows 174a, 174b, 174c, and 174d in a vacuum state through the through-holes 172-1 (in FIG. 7D) formed in the upper chamber 172.

The first to fourth upper table wafer stages 171a, 171b, 171c, and 171d may be vacuum-tight by the first to fourth bellows 174a, 174b, 174c, and 174d. The first to fourth UVW alignment stages 173a, 173b, 173c, and 173d may have mobility without breaking vacuum tightness.

The first to fourth upper table wafer stages 171a, 171b, 171c, and 171d may be connected to the vacuum pump through the first to fourth bellows 174a, 174b, 174c, and 174d from the upper chamber 172.

The vision unit 179 (in FIG. 7B) may be installed on the side of the lower table VAS module 170B, and may be installed in pairs of two for each of the first to fourth upper table wafer stages 171a, 171b, 171c, and 171d. The vision unit 179 may include first to eighth high-resolution vision units 179a to 179h that precisely adjust each UVW alignment stage 173 in the 3-axis UVW direction.

The vacuum chucks 175a, 175b 175c, and 175d, which are attached to each of the above-mentioned four upper table wafer stages 171a, 171b, 171c, and 171d, may include a vacuum chuck pipe 175-3 and a vacuum chuck pipe ring housing 175-5. The vacuum chuck pipe 175-3 may operate vacuum suction. The vacuum chuck pipe ring housing 175-5 may airtightly accommodate the vacuum chuck pipe 175-3. The vacuum chuck driving unit 177 may raise and lower the vacuum chucks 175a, 175b 175c, and 175d and may be positioned above the UVW alignment stage 173.

The second transfer module 190 (in FIG. 3) may include a transfer robot 191 having a double arm and two transfer hands 193 and 195, respectively, attached to the double arm.

The first transfer hands 193 may be configured to transfer the cover glass 15 to the aforementioned lower table VAS module 170B, and the second transfer hand 195 may be configured to simultaneously transfer the set of wafers 11′ and the cover glass 15, which are bonded to each other.

Accordingly, one of the transfer hands 193 and 195 may be used only for transferring the cover glass 15, and the other may be used for taking out the set of wafers 11′ and the cover glass 15, which are bonded to each other, from the VAS device 170.

The second transfer hand 195 may be discharged through a transfer passage, through which a glass having the size of about 650 mm×750 mm is returned.

A turn function may be performed through the passage, and the passage may have a two-stage structure according to the transportation configuration.

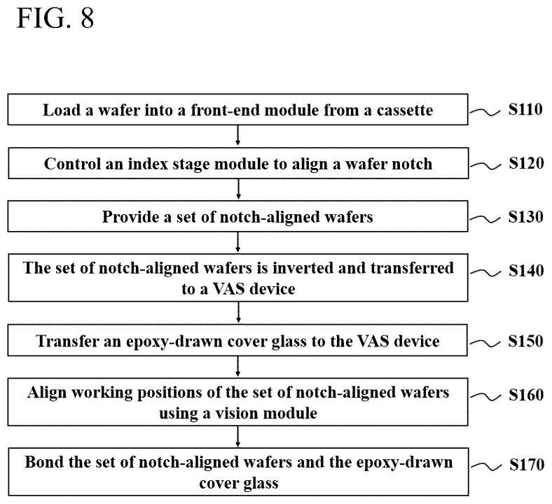

Referring to FIG. 8, a bonding method between a set of carrier-free OLEDoS wafers 11′ and a cover glass 15 according to an embodiment will be described.

As shown in FIG. 8, in the control method of the bonding system 1 for carrier-free OLEDoS wafers 11′ and a cover glass 15, the control module 300 may be loaded into the front-end module 110 of the bonding system 1, may control the extraction robot 113 to take out the OLEDoS wafers 11′ from the cassette 111 in units of sheets (or one by one) (S110), and may control the index stage module 130 to align the OLEDoS wafers 11′, which are taken out from the cassette 111, using notches 11a, 11b, 11c, and 11d of the OLEDoS wafers 11′ (S120). In case that it is determined that the first to fourth compartments 131A, 131B, 131C, 131D of the index stage 131 are empty through communication with the index stage 131 of the index stage module 130, the set of notch-aligned wafers 11′ may be provided by sequentially arranging first to fourth wafers 11A, 11B, 11C, and 11D among the OLEDoS wafers 11′ taken out from the front-end module 110 in units of sheets (or one by one) (S130). The set of notch-aligned wafers 11′ may be taken out from the index stage module 130, may be entirely inverted one time, and may be transferred to the upper table VAS module 170A of the upper surface of the VAS device 170 (S140). The second transfer module 190 may communicate with the cover glass preparation stage 200 to transfer the epoxy-drawn cover glass 15′ to the lower table VAS module 170B of the VAS device 170 (S150). The control module 300 may communicate with the vision module 180 for fine alignment of the first to fourth wafers 11A, 11B, 11C, and 11D using each of the first to fourth notches 11a, 11b, 11c, and 11d, and may control the front-end module 110, the index stage module 130, the first transfer module 150, the VAS device 170, and the second transfer module 190 to align the working positions of the first to fourth wafers 11A, 11B, 11C, and 11D of the set of wafers 11′, respectively, through the communication with the vision module 180 (S160). The set of notch-aligned wafers 11′, which are transferred in a first direction in an inverted state by the first transfer module 150 and disposed on the upper table VAS module 170A, and the epoxy-drawn cover glass 15′, which is transferred in a second direction opposite to the first direction by the second transfer module 190 and disposed on the lower table VAS module 170B under a vacuum atmosphere, may be joined or attached by controlling the upper and lower table VAS modules of the VAS device 170 (S170).

It may be determined whether the upper table wafer stage 171 of the upper table VAS module 170A is in an empty state before transferring the inverted set of wafers 11′ from the first transfer module 150 through the communication with the upper table VAS module 170A. After confirming that the upper table wafer stage 171 is in an empty state, the robot hand 153 may forwardly moves the inverted set of wafers 11′ with respect to the upper table wafer stage 171, and may align each of the upper table wafer stages 171 to the first to fourth wafers 11A, 11B, 11C, and 11D of the set of wafers 11′. Further, the vacuum chuck unit 175 may be lowered in the upper table VAS module 170A to lower the set of wafers 11′, and may adsorb each wafer.

The robot hand 153 may move upward and backward from the set of wafers 11′, and in case that the robot hand 153 moves upward and backward from the set of wafers 11′, the vacuum chuck unit 175 of the upper table wafer stage 171 may move up to disposed the set of wafers 11′ including first to fourth wafers 11A, 11B, 11C, and 11D on the upper table wafer stage 171.

The control module 300 may control the robot hand 153 to sequentially transfer the wafers, which are notch-aligned by the first and second wafer notch alignment devices 117a and 117b, to the empty first, second, third, and fourth compartments 131A, 131B, 131C, and 131D of the index stages 131 of the index stage module 130 on by one. The wafers put into the index stage 131 may be disposed on the seating pins 135 installed in the center area of each of the first to fourth compartments and driven independently. In case that the first, second, third, and fourth compartments 131A, 131B, 131C, and 131D are sequentially filled with the first to fourth wafers 11A, 11B, 11C, and 11D, the index stage 131 may be rotated according to the drive type of the first to fourth angles where the notch alignment of each of the first to fourth wafers 11A, 11B, 11C, and 11D may be performed.

By the first to fourth angle drive-type swivel drive method, the index stage 131 may form a set of wafers 11′ filled with the above-mentioned first to fourth wafers 11A, 11B, 11C, and 11D in a notch-aligned state in the first to fourth compartments 131A, 131B, 131C, and 131D.

According to another aspect of the invention, the upper table VAS module 170a may also have four cover glasses 15 corresponding to the size of the wafer.

Thus, there is a problem in that the bonding system 1 becomes more complicated since the upper table VAS module 170a should also include four UVW alignment stages 173 and four vision module 180 to enable epoxy drawing.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A cover glass bonding method, the method comprising:
aligning each wafer of a set of organic light-emitting diode on silicon (OLEDoS) wafers and disposing the set of OLEDoS wafers on an upper table vacuum assembly system (VAS) module of a VAS device without using a carrier glass;
disposing an epoxy-drawn cover glass on a lower table VAS module of the VAS device;
bonding the set of OLEDoS wafers and the epoxy-drawn cover glass, wherein
a working position of each wafer of the set of OLEDoS wafers is individually controlled in the upper table VAS module of the VAS device.

2. The cover glass bonding method of claim 1, wherein:
the set of OLEDoS wafers includes first, second, third, and fourth wafers,
each of the first, second, third, and fourth wafers has a circular shape having a diameter of about 300 mm,
the epoxy-drawn cover glass has a square shape having a size of about 650 mm×750 mm,
the first and second wafers have first and second notches arranged side by side on an upper portion of the set of OLEDoS wafers in a first row, and
the third and fourth wafers have third and fourth notches arranged side by side on a lower portion of the set of OLEDoS wafers in a second row, and
the third and fourth notches are arranged to the first and second notches in a straight line to bond the set of OLEDoS wafers and the epoxy-drawn cover glass.

3. The cover glass bonding method of claim 2, wherein:
the epoxy-drawn cover glass include first, second, third, and fourth vision alignment marks corresponding to the first, second, third, and fourth notches of the first, second, third, and fourth wafers.

4. A bonding system of a cover glass comprising:
a front-end module that takes out wafers from a cassette;
an index stage module that forms a set of notch-aligned wafers through notch-alignment of first, second, third, and fourth wafers transferred from the front-end module;
a first transfer module that takes out the set of notch-aligned wafers formed in the index stage module, inverts the set of notch-aligned wafers one time, and transports and places the set of notch-aligned wafers on an upper table vacuum assembly system (VAS) module of a vacuum assembly system (VAS) device;
a second transfer module that transports and arranges a cover glass, which is drawn with epoxy in a cover glass preparation stage, to a lower table VAS module of the VAS device; and
the VAS device that bonds the epoxy-drawn cover glass and the set of notch-aligned wafers in a vacuum atmosphere, the set of notch-aligned wafers transferred in a first direction in an inverted state by the first transfer module and disposed on the upper table VAS module, the epoxy-drawn cover glass transferred in a direction opposite to the first direction by the second transfer module and disposed on the lower table VAS module.

5. The bonding system of the cover glass of claim 4, wherein:
each of the first, second, third, and fourth wafers has a circular shape having a diameter of about 300 mm,
the cover glass has a square shape having a size of about 650 mm×750 mm, and
the set of notch-aligned wafers and the cover glass are bonded to each other.

6. The bonding system of the cover glass of claim 4, comprising:
a vision module that aligns the first, second, third, and fourth wafers using first through fourth notches of the first, second, third, and fourth wafers, respectively; and
a control module that controls the front-end module, the index stage module, the first transfer module, the VAS device, and the second transfer module through electrically communicating with the vision module.

7. The bonding system of the cover glass of claim 6, wherein:
the front-end module includes:
an extraction robot that takes out the wafers from the cassette, and
first and second wafer notch alignment devices that communicate with the control module, the first and second wafer notch alignment device disposed at an end portion of a robot arm of the extraction robot, and
the first and second wafer notch alignment devices optimizes a processing time balance of the index stage module.

8. The bonding system of the cover glass of claim 7, wherein:
the index stage module has a shape and a size corresponding to the shape and the size of the cover glass, and
the index stage module includes:
an index stage that supports first, second, third, and fourth compartments in which the first, second, third, and fourth wafers are sequentially filled to be notch-aligned, the index stage that informs indexes of the empty first, second, third, and fourth compartments so that the control module operates and controls the extraction robot, the first and second wafer notch alignment devices, and the robot arm, and
a stage drive unit that drives the index stage in first, second, third, and fourth type methods in which the first, second, third, and fourth wafers aligned by first and second wafer notch alignment devices are sequentially aligned and arranged by the robot arm, and
the first, second, third, and fourth compartments include:
seating pins disposed at a center area of each of the first, second, third, and fourth wafers to seat the first, second, third, and fourth wafers, and
index alignment marks corresponding to the first, second, third, and fourth notches of the first, second, third, and fourth wafers.

9. The bonding system of the cover glass of claim 4, wherein:
the first transfer module includes:
a robot hand that adsorbs and fixes the set of notch-aligned wafers upward, and
a rotatable robot that rotates the robot hand downward to invert the set of notch-aligned wafers, and
the robot hand includes:
a first finger that adsorbs and supports the first and second wafers, and
a second finger spaced apart from the first finger by a distance and adsorbing and supporting the third and fourth wafers.

10. The bonding system of the cover glass of claim 6, wherein:
the control module communicates with the upper table VAS module to confirm that upper table wafer stages of the upper table VAS module is in an empty state before a set of inverted wafers is transferred from the first transfer module, and
a robot hand moves the set of inverted wafers forward with respect to the upper table wafer stages,
the first, second, third, and fourth wafers of the set of notch-aligned wafers are aligned with respect to each of the upper table wafer stages, and
a vacuum chuck is lowered to adsorb each wafer of the set of notch-aligned wafers,
the robot hand moves upward and backward from the set of notch-aligned wafers, and
in case that the robot hand moves upward and backward from the set of notch-aligned wafers, the vacuum chuck is raised to control the first, second, third, and fourth wafers of the set of wafers to be disposed on the upper table wafer stages, and
the vacuum chuck moves up and down between first and second fingers of the robot hand.

11. A vacuum assembly system (VAS) device for a bonding system for a plurality of organic light-emitting diode on silicon (OLEDoS) wafers and a cover glass, the VAS device comprising:
an upper table VAS module disposed on an upper side of the VAS device; and
a lower table VAS module disposed on a lower side of the VAS device,
wherein the upper table VAS module comprises:
first, second, third, and fourth upper table wafer stages on which first, second, third, and fourth wafers of a set of four wafers are respectively seated in notch alignment;
a UVW alignment stage including first, second, third, and fourth UVW alignment stages that are connected to the first, second, third, and fourth upper table wafer stages and independently perform 3-axis UVW alignment on each of the first, second, third, and fourth upper table wafer stages;
a vacuum chuck unit including first, second, third, and fourth vacuum chucks that place the first, second, third, and fourth wafers on the first, second, third, and fourth upper table wafer stages, respectively;
a vacuum chuck driving unit including first, second, third, and fourth vacuum chuck driving units that elevate and lower the vacuum chuck unit; and
first, second, third, fourth, fifth, sixth, seventh and eighth high-resolution vision units provided in pairs for each of the first, second, third, and fourth upper table wafer stages and communicating with a control module so that the UVW alignment stage is adjusted in a 3-axis UVW direction.

12. The VAS device for the bonding system of claim 11, wherein:
the first, second, third, and fourth upper table wafer stages are disposed in an upper chamber,
the UVW alignment stage is disposed outside the upper chamber,
the vacuum chuck driving unit is disposed outside the UVW alignment stage,
the first, second, third, fourth, fifth, sixth, seventh, and eighth high-resolution vision units correspond to the first, second, third, and fourth upper table wafer stages, respectively, and are disposed below the first, second, third, and fourth upper table wafer stages.

13. The VAS device for the bonding system of claim 12, wherein:
the UVW alignment stage includes:
first, second, third, and fourth base substrates connected through a communication hole of the upper chamber, and
first, second, third, and fourth UVW drivers corresponding to the first, second, third, and fourth upper table wafer stages, the first, second, third, and fourth UVW drivers that drive the first, second, third, and fourth base substrates in three axes to compensate for displacement of working positions of the first, second, third, and fourth base substrates.

14. The VAS device for the bonding system of claim 12, wherein:
the vacuum chuck unit of the upper table VAS module includes:
a vacuum chuck pad connected to each of the first, second, third, and fourth upper table wafer stages,
a vacuum chuck pipe that provides vacuum negative pressure to the vacuum chuck pad, and
a vacuum chuck pipe ring housing that prevents leak between a bottom of the vacuum chuck pipe and the vacuum chuck pad, and
the vacuum chuck pipe is at least partially connected to the vacuum chuck driving unit to raise and lower the vacuum chuck pad to be exposed outside of the upper chamber.

15. The VAS device for the bonding system of claim 14, further comprising:
bellows disposed in the upper chamber to provide negative vacuum pressure to the first, second, third, and fourth upper table wafer stages to independently drive the first, second, third, and fourth upper table wafer stages and the UVW alignment stage; and
adapters connecting a lower part of the UVW alignment stage and an upper part of the upper chamber, and
wherein the bellows and the adapters overlap the first, second, third, and fourth upper table wafer stages and the UVW alignment stage, respectively.

16. The VAS device for the bonding system of claim 14, further comprising:
a second transfer module including:
a first transfer hand that transfers the cover glass to the lower table VAS module, and
a second transfer hand that transfers the set of four wafers and the cover glass that are bonded to each other, wherein
the first transfer hand and the second transfer hand are disposed opposite to each other, and are connected to a transfer passage.

17. A control method of a bonding system of a plurality of carrier-free organic light-emitting diode on silicon (OLEDoS) wafers and a cover glass, the method comprising:
controlling an extraction robot to take out wafers from a cassette loaded in a front-end module of the bonding system by a control module;
controlling an index stage module to align the wafers taken out by the extraction robot using notches of the wafers;
sequentially arranging first, second, third, and fourth wafers among the wafers to form a set of notch-aligned wafers in case that it is determined that first, second, third, and fourth compartments of an index stage are empty through communication with the index stage of the index stage module;
communicating with a first transfer module to take out the set of notch-aligned wafers, to invert the set of notch-aligned wafers one time, and controlling transfer and placement of the set of notch-aligned wafers to an upper table vacuum assembly system (VAS) module of a VAS device; and
communicating with a second transfer module and controlling transfer and arrangement of the cover glass drawn with epoxy in a cover glass preparation stage to a lower table VAS module of the VAS device; and
controlling the upper table VAS module and the lower table VAS module of the VAS device to bond the set of notch-aligned wafers disposed in the upper table VAS module by the first transfer module in an inverted state in a first direction, and the epoxy-drawn cover glass disposed in the lower table VAS module by the second transfer module in a second direction opposite to the first direction, under a vacuum atmosphere.

18. The control method of the bonding system of claim 17, further comprising:
communicating with a vision module for alignment of the first, second, third, and fourth wafers using the first, second, third, and fourth notches of the first, second, third, and fourth wafers, respectively; and
controlling working positions of the front-end module, the index stage module, the first transfer module, the VAS device, and the second transfer module through communicating with the vision module.

19. The control method of the bonding system of claim 18, further comprising:
communicating with the upper table VAS module and confirming that an upper table wafer stage of the upper table VAS module is empty before the set of inverted notch-aligned wafers is transferred from the first transfer module;
moving the set of inverted notch-aligned wafers forward with respect to the upper table wafer stage by a robot hand;
aligning the first, second, third, and fourth wafers of the set of notch-aligned wafers with respect to each of the upper table wafer stages;
adsorbing each wafer of the set of notch-aligned wafers by lowering a vacuum chuck in the upper table VAS module; and
placing the first, second, third, and fourth wafers of the set of notch-aligned wafers on the upper table wafer stage by moving the robot hand upward and backward from the set of notch-aligned wafers such that the vacuum chuck of the upper table wafer stage moves up.

20. The control method of the bonding system of claim 19, further comprising:
disposing the wafers, which are notch-aligned by first and second wafer notch alignment devices, one by one to the first, second, third, and fourth compartments of the index stage of the index stage module;
disposing the wafers, which are loaded into the index stage, on a seating pin disposed in a center area of each of the first, second, third, and fourth compartments and driven independently;
driving the index stage according to first, second, third, and fourth angular driving types in which the notches of the first, second, third, and fourth wafers are aligned in case that the first, second, third, and fourth compartments are sequentially filled with the first, second, third, and fourth wafers; and
forming a set of wafers, which are filled in the first, second, third, and fourth compartments in order with the first, second, third, and fourth wafers being notched-aligned in first, second, third, and fourth angular driving types.
